(19) United States
(12) Patent Application Publication
(10) Pub. No.: US 2026/0255534 A1
(43) Pub. Date: Aug. 27, 2026

(54) REPOSITIONABLE MANIFOLD ASSEMBLY FOR IMPROVED SERVICEABILITY OF A SERVER

(71) Applicant: Lenovo Global Technology (UnitedStates) Inc., Morrisville, NC (US)

(72) Inventors: YuSyuan Lin, New Taipei City (TW); Ting Yuan Fang, New Taipei City (TW); Bejoy Jose Kochuparambil, Apex, NC (US); Arvind Modekurti, Cary, NC (US)

(21) Appl. No.: 19/060,718

(22) Filed: Feb. 23, 2025

(51) Int. Cl. H05K 7/20

(52) U.S. Cl. CPC H05K 7/20272; H05K 7/20254; H05K 7/20772

(57) ABSTRACT

An apparatus includes a server chassis containing a lateral row of processing unit assemblies that each include a processing unit and a cold plate. A repositionable manifold assembly within the server chassis includes a rigid manifold bracket, a liquid supply manifold, and a liquid return manifold. A plurality of flexible manifold hoses are connected to the manifold assembly and extend rearward therefrom. The flexible manifold hoses include a manifold liquid supply hose, a manifold liquid return hose and, for each cold plate, a cold plate liquid supply hose and a cold plate liquid return hose. The manifold assembly is selectively securable in an operative position forward of the lateral row of processing unit assemblies and extends laterally over various components, and selectively securable in a service position rearward of the components to enable a service operation on any of the various components without disconnecting any of the flexible manifold hoses.

### BACKGROUND

The present disclosure relates to a server having multiple liquid cooled processing units.

### BACKGROUND OF THE RELATED ART

Servers that include multiple processing units produce a significant amount of heat. This is particularly true for servers having several graphics processing units operating in a compact server chassis, such as might be used to support artificial intelligence applications. For example, the current generation of servers designed for handling artificial intelligence (AI) models include several graphics processing units (GPUs), such as a set of eight GPUs packed together in a single server chassis. The compact arrangement of these GPUs makes serviceability and replacement of the GPU module difficult. For example, these high performance GPUs typically require liquid cooling using a cold plate secured over the top of each GPU.

To avoid thermal damage of the processing units, the processing units may be liquid cooled. Specifically, a cooled liquid may be circulated through cold plates that are in thermal communication with the processing units. These cold plates are typically made using heavy copper metal plates, which have a high thermal conductivity. Since each cold plate needs a liquid supply hose and a liquid return hose, a server containing several cold plates can become physically congested with hoses and fluid distribution manifolds such that serviceability and replacement of a single processing unit can be extremely difficult. For example, the mechanical interference of the hoses themselves may make it difficult to remove a cold plate prior to accessing the processing unit.

The number of hoses and hose connections may be reduced by using larger cold plates or assemblies that cool multiple processing units. However, removing these larger cold plates or assemblies will expose each of the multiple processing units even if only one processing unit needs to be serviced or replaced. However, using such large cold plates means shutting down all of the corresponding processing units, exposing each of those processing units to mechanical forces, and handling a rather large cold plate. Cold plates are often made of copper and may be heavy and bulky. Such a large and heavy cold plate can get in the way of a service action even and/or may cause damage to the base die silicon of a processing unit module if the cold plate is mishandled.

In some systems, the liquid supply and return hoses may be connected to the cold plates using a quick disconnect coupling. With the use of quick disconnect couplings, the hoses can be moved out of the way quickly to enable removal of the cold plate and servicing of the processing unit. However, quick disconnect couplings are expensive and come with the risk of leaking cooling liquid inside the server during disconnection of the couplings prior to service or reconnection of the couplings after service. For example, a quick disconnect coupling may leak as the result of a malfunctioning internal valve or seal.

A cold plate must be carefully set aside during servicing of the processing unit to avoid physical damage to either the cold plate or the processing unit and to avoid interference with servicing of the processing unit. Regardless of the specific manner in which hose interference issues are addressed, adding steps to a process of accessing an individual processing unit in the server increases the time and cost of performing a service action.

### BRIEF SUMMARY

Some embodiments provide an apparatus comprising a server chassis containing a rear lateral row of processing unit assemblies secured to a system board, wherein each processing unit assembly includes a processing unit and a cold plate in thermal communication with the processing unit. The apparatus further comprises a repositionable manifold assembly positioned within the server chassis and including a first rigid manifold bracket, a first liquid supply manifold secured to the first rigid manifold bracket, and a first liquid return manifold secured to the first rigid manifold bracket. Still further, the apparatus comprises a first plurality of flexible manifold hoses connected to the repositionable manifold assembly and extending rearward from the repositionable manifold assembly, wherein the first plurality of flexible manifold hoses include a first manifold liquid supply hose connected to an inlet to the first liquid supply manifold, a first manifold liquid return hose connected to an outlet from the first liquid return manifold and, for each cold plate in the rear lateral row, a cold plate liquid supply hose connected from an outlet of the first liquid supply manifold to an inlet to the cold plate and a cold plate liquid return hose connected from an outlet of the cold plate to an inlet of the first liquid return manifold. Furthermore, the first repositionable manifold assembly is selectively securable in an operative position forward of the rear lateral row of processing unit assemblies and extends laterally over a plurality of components on the system board, and the first repositionable manifold assembly is selectively securable in a service position rearward of the plurality of components to enable a service operation on any one or more of the plurality of components without disconnecting any of the first plurality of flexible manifold hoses.

### BRIEF DESCRIPTION OF THE SEVERAL VIEWS OF THE DRAWINGS

FIG. 1A is a perspective view of a server having eight (8) processing unit assemblies arranged in front and rear lateral rows and stationary (front) and repositionable (rear) manifold assemblies in their operative positions.

FIG. 1B is a top (plan) view of the server.

FIGS. 2A-B are bottom perspective views of a rigid manifold bracket and a repositionable (rear) manifold assembly including the rigid manifold bracket, a liquid supply manifold, and a liquid return manifold.

FIGS. 2C-D are bottom perspective views of a rigid manifold bracket and a stationary (front) manifold assembly including the rigid manifold bracket, a liquid supply manifold, and a liquid return manifold.

FIG. 3 is a perspective view of a cold plate including a cooling liquid inlet, a cooling liquid outlet and a top plate.

FIGS. 4A-B are partial side perspective views showing the repositionable manifold assembly secured in a shipping position using a first (shipping) adapter bracket and a pair of handle brackets

FIGS. 5A-B are perspective views of the first adapter bracket with and without the pair of handle brackets.

FIGS. 6A-B are back and front views of the first adapter bracket.

FIG. 7A-B are schematic top views of the first adapter bracket and the repositionable manifold assembly before and after forming a temporary connection that secures the repositionable manifold assembly in a service position.

FIGS. 8A-B are upright and upside-down perspective views of a second (service) adapter bracket.

FIG. 9A is a partial side view of the server of FIG. 1 with the first adapter bracket secured to the cold plates in the rear row of processing unit assemblies.

FIG. 9B is a partial side view as in FIG. 9A after the repositionable (rear) manifold assembly has been temporarily connected to the first adapter bracket to be secured in a service position.

FIG. 9C is a partial side view as in FIG. 9B with a second (service) adapter bracket secured to a cold plate in the front lateral row of processing unit assemblies.

FIG. 9D is a partial side view as in FIG. 9C after the cold plate in the front lateral row of processing unit assemblies has been temporarily connected to the stationary (front) manifold assembly to provide unobstructed access to the processing unit.

FIGS. 9E-F are partial side views as in FIGS. 9C-D using a different configuration of the second (service) adapter bracket to secure the cold plate in a different position while providing unobstructed access to the processing unit.

FIGS. 9G-J are partial side views as in FIG. 9A where the second (service) adapter bracket is secured to one of the cold plates in the rear lateral row of processing unit assemblies and subsequently used to form a temporary connection to the repositionable (rear) manifold assembly in order to provide unobstructed access to the processing unit.

FIGS. 10A-B are partial perspective views of one side of the server chassis including attachment points for securing the repositionable manifold assembly in the service position and the operative position, respectively.

FIG. 11 is a schematic diagram illustrating the cooling liquid inlet and outlet connections and the pathway cooling liquid through a cold plate.

FIGS. 12A-B are schematic side views of a generic connection between two components that may be used to form connections according to various embodiments.

FIGS. 13A-D are schematic plan views of a cap screw and two guide pins as they may be arranged on a component to form a connection.

### DETAILED DESCRIPTION

Some embodiments provide a repositionable manifold assembly for improved serviceability of a server, such as the serviceability of components on a system board that have obstructed access due to an operative position of the manifold assembly being directly over the components. While the operative position of the repositionable manifold assembly obstructs access to the components, embodiments provide a first bracket that can be used to temporarily secure the repositionable manifold assembly in a service position that no longer obstructs access to the components.

Some embodiments provide a repositionable cold plate for improved serviceability of a server, such as the serviceability of a processing unit in thermal communication with a cold plate that obstructs access to the processing unit. While the operative position of the cold plate obstructs access to the processing unit, embodiments provide a second bracket that can be used to temporarily secure the cold plate in a service position that no longer obstructs access to the processing unit.

Some embodiments combine the repositionable manifold assembly and the repositionable cold plate. For example, the first bracket may be used to temporarily secure the repositionable manifold assembly in the service position to enable unobstructed access to a component on the system board, where the component on the system board is a processing unit assembly that includes a cold plate and a processing unit in thermal communication with the cold plate. With the repositionable manifold assembly secured to the first bracket to provide unobstructed access to the processing unit assembly, the second bracket may be used to secure the cold plate in the service position to enable unobstructed access to the processing unit. Such embodiments are particularly beneficial in servers that include two rows of processing units that require liquid cooling cold plates. In such embodiments, the manifold assembly that supplies fluid cooling to a rear row of processing unit assemblies may obstruct access to a front row of processing unit assemblies and a cold plate in the front row of processing unit assemblies can obstruct access or cause damage during a service action on a processing unit in the front row.

The description of the embodiments may describe one embodiment separately from another, but it should be understood that the embodiments may be combined with significant benefit. By contrast, the drawings and description of the drawings show a combined embodiment, but it should be understood that either embodiment may be used separately and still provide significant benefits.

### Repositionable Manifold Assembly for Improved Serviceability of a Server

Some embodiments provide an apparatus comprising a server chassis containing a rear lateral row of processing unit assemblies secured to a system board, wherein each processing unit assembly includes a processing unit and a cold plate in thermal communication with the processing unit. The apparatus further comprises a repositionable manifold assembly positioned within the server chassis and including a first rigid manifold bracket, a first liquid supply manifold secured to the first rigid manifold bracket, and a first liquid return manifold secured to the first rigid manifold bracket. Still further, the apparatus comprises a first plurality of flexible manifold hoses connected to the repositionable manifold assembly and extending rearward from the repositionable manifold assembly, wherein the first plurality of flexible manifold hoses include a first manifold liquid supply hose connected to an inlet to the first liquid supply manifold, a first manifold liquid return hose connected to an outlet from the first liquid return manifold and, for each cold plate in the rear lateral row, a cold plate liquid supply hose connected from an outlet of the first liquid supply manifold to an inlet to the cold plate and a cold plate liquid return hose connected from an outlet of the cold plate to an inlet of the first liquid return manifold. Furthermore, the first repositionable manifold assembly is selectively securable in an operative position forward of the rear lateral row of processing unit assemblies and extends laterally over a plurality of components on the system board, and the first repositionable manifold assembly is selectively securable in a service position rearward of the plurality of components to enable a service operation on any one or more of the plurality of components without disconnecting any of the first plurality of flexible manifold hoses.

In some embodiments, the apparatus may have front and rear rows of processing unit assemblies. However, in other embodiments, the repositionable manifold assembly may be beneficial to provide access to other serviceable components installed near and/or in place of a front row of processing unit assemblies. Accordingly, it should be understood that reference to “a rear lateral row of processing unit assemblies” does not require an embodiment to include “a front lateral row of processing units”. Rather, “a rear lateral row of processing unit assemblies” indicates that there is some plurality of components on the system board forward of (i.e., in front of) the rear lateral row of processing unit assemblies.

The system board is a printed circuit board that supports the operation of the processing unit assemblies within the server. For example, the system board may provide power distribution, memory, data storage, network interfaces, and/or system management available to the processing units.

The processing unit within each processing unit assembly may be a central processing unit (CPU), a graphics processing unit (GPU) or other type of high performance processing unit. In one option, each processing unit is a graphics processing unit that is suitable for performing artificial intelligence models. Some servers may have as many as four graphics processing units positioned side-by-side in the rear lateral row of processing unit assemblies. Furthermore, the plurality of components forward of the rear lateral row may include as many as four additional graphics processing units in a front lateral row of processing unit assemblies. Other configurations of a server may also benefit from the repositionable manifold assembly and/or the repositionable cold plate embodiments disclosed herein.

The cold plate within each processing unit assembly is a component that is used to manage the heat generated by a high-performance processing unit within the same processing unit assembly. The cold plate typically includes a metal plate, often made of copper or aluminum, which offers high thermal conductivity. The plate interfaces directly with the processing unit, such as a heat spreader secured to the processing unit, ensuring efficient heat transfer from the processing unit to the cold plate. Internally, the cold plate may include channels or grooves that allow a cooling liquid (i.e., “coolant”) to flow evenly through the plate. As the cooling liquid absorbs heat from the CPU, the circulating cooling liquid carries the heat away. The surface of the cold plate may be machined to achieve a flat and smooth contact area for engaging the processing unit, often accompanied by a layer of thermal paste that is applied to eliminate air gaps and enhance thermal conductivity. An external source of the cooling fluid may include pumps that ensure the cooling liquid continuously circulates through the cold plate to maintain a consistent or suitable operating temperature of the processing unit.

In some embodiments, the first plurality of flexible manifold hoses may be made from a flexible polymer material that is compatible with the coolant. A preferred coolant includes water, such as a deionized water, but the coolant may include a mixture of water and a glycol composition, such as ethylene glycol or propylene glycol. However, the coolant may further include a synthetic mineral oil or dielectric fluid. The flexible polymer material may be a flexible poly vinyl chloride (PVC) or an ethylene propylene diene monomer (EPDM) rubber.

In some embodiments, for each cold plate in the rear lateral row, the cold plate includes a barbed liquid inlet coupling that is connected to one of the cold plate liquid supply hoses and a barbed liquid outlet coupling that is connected to one of the cold plate liquid return hoses. Optionally, the apparatus may include a plurality of hose clamps, wherein, for each cold plate liquid supply hose, one of the hose clamps secures an end of the cold plate liquid supply hose to one of the barbed liquid inlet couplings, and wherein, for each cold plate liquid return hose, one of the hose clamps secures an end of the cold plate liquid return hose to one of the barbed liquid outlet couplings. Some embodiments may further include, for each cold plate in the rear lateral row of processing unit assemblies, a barbed liquid outlet coupling of the liquid supply manifold that is connected to an opposing end of the cold plate liquid supply hose and a barbed liquid inlet coupling of the liquid return manifold that is connected to an opposing end of the cold plate liquid return hose. Optionally, one of the hose clamps secures the opposing end of the cold plate liquid supply hose to the barbed liquid outlet coupling and another of the hose clamps secures the opposing end of the cold plate liquid return hose to the barbed liquid inlet coupling. The combination of the barbed couplings and the hose clamps provide a reliable seal that is unlikely to leak and may be used in the various embodiments because there is no need to ever disconnect any of the hoses from any of the cold plates. Accordingly, embodiments provide the technical benefit of providing access and serviceability to components on the system board without requiring any disconnection of the hoses in the liquid distribution system.

In some embodiments, the apparatus further comprises a first adapter bracket selectively securable to one or more of the cold plates in the rear row of processing unit assemblies. Accordingly, the repositionable manifold assembly may be selectively securable in the service position by selectively securing the rigid manifold bracket of the repositionable manifold assembly to the first adapter bracket that has been secured to the one or more cold plates. In one option, the first adapter bracket includes a first fastener part, the rigid manifold bracket includes a second fastener part, and the repositionable manifold assembly is selectively securable to the first adapter bracket by securing the first fastener part to the second fastener part. For example, the first fastener part may be selected from a keyhole slot and a T-pin that is selectively securable to the keyhole slot by sliding a head of the T-pin into the keyhole slot, wherein the second fastener part is the other of the keyhole slot or the T-pin. In another option, the first adapter bracket includes two or more of the first fastener parts laterally spaced apart and the rigid manifold bracket includes two or more of the second fastener parts aligned with the two or more of the first fastener parts.

In some embodiments, the first rigid manifold bracket may include a first lateral end and a second lateral end, wherein the repositionable manifold assembly is selectively securable in the operative position with the first lateral end of the first rigid manifold bracket connected to a first lateral side of the server chassis and the second lateral end of the first rigid manifold bracket connected to a second lateral side of the server chassis, and wherein the repositionable manifold assembly is selectively securable in the service position by coupling the first rigid manifold bracket to the first adapter bracket. Optionally, moving the repositionable manifold assembly between the operative position and the service position includes rotating the repositionable manifold assembly about a lateral axis of the repositionable manifold assembly. The rotation of the repositionable manifold assembly during movement from the operative position to the service position may reduce wear and/or kinking of the plurality of flexible hoses connected to the repositionable manifold assembly.

In some embodiments, the first adapter bracket may include two or more face plates and each face plate may have a pair of alignment pins and cap screw. Each cold plate may include a top plate having a pair of alignment holes and a threaded hole such that positioning the face plates over the top plates and inserting the pair of alignment pins into the pair of alignment holes aligns the cap screw and the threaded hole. Subsequently, the cap screw may be threaded into the threaded hole to secure each of the face plates to the top plates of separate cold plates. The first adapter bracket may also include connectors for temporarily securing the repositionable manifold in a service position rather than the operative position to facilitate service actions and/or assembly actions. Placing the repositionable manifold in the service position prevents the repositionable manifold and any hoses connected to the repositionable manifold assembly from causing any mechanical interference or obstruction with access and/or removal of a front cold plate for servicing a front component, such as a processing unit. It is a technical benefit that the front components may be serviced without removal of the rear cold plate.

In some embodiments, the first adapter bracket may serve a dual purpose by being used during shipping of the server as well as during a service operation. For example, apparatus may further comprise a handle bracket selectively securable between the first adapter bracket and the first rigid manifold bracket with the first adapter bracket secured to the one or more of the cold plates in the rear lateral row and with the repositionable manifold assembly placed in a shipping position. The shipping position may be different than the operative position and the service position. The handle bracket may be dedicated to a shipping configuration of the server and may be removed when the server is being prepared for operation. Furthermore, the first adapter bracket may also be removed when the service is being prepared for operation but may be kept available for use during a service operation in which the repositionable manifold assembly is beneficially moved to the service position.

In some embodiments, the plurality of components on the system board form a front row of processing unit assemblies in front of the rear row of processing unit assemblies. In such embodiments, the apparatus may further comprise a stationary manifold assembly secured in the server chassis forward of the front row of processing unit assemblies and a second plurality of flexible manifold hoses connected to the stationary manifold assembly and extending rearward from the stationary manifold assembly. The second plurality of flexible manifold hoses may include a second manifold liquid supply hose connected to an inlet to the second liquid supply manifold, a second manifold liquid return hose connected to an outlet from the second liquid return manifold and, for each cold plate in the front row, a cold plate liquid supply hose connected from an outlet of the second liquid supply manifold to an inlet to the cold plate and a cold plate liquid return hose connected from an outlet of the cold plate to an inlet of the second liquid return manifold.

In some embodiments having both the repositionable manifold assembly and the stationary manifold assembly, the first manifold liquid supply hose and the first liquid return hose may extend rearward from the repositionable manifold assembly and out the rear of the server chassis, and the second liquid supply hose and the second liquid return hose extend rearward from the stationary manifold assembly and out the rear of the server chassis. In one option, for each cold plate in the rear lateral row and each cold plate in the front lateral row, the cold plate liquid supply hose and the cold plate liquid return hose that are connected to the cold plate do not pass over any other cold plate in the same row as the cold plate. In another option, the first manifold liquid supply hose may be connected to a first lateral side of the rear liquid supply manifold and extends rearward along a first lateral side of the server chassis, the rear liquid return hose may be connected to a second lateral side of the rear liquid return manifold and extends rearward along a second lateral side of the server chassis, the second manifold liquid supply hose may be connected to a first lateral side of the second liquid supply manifold and extends rearward along the first lateral side of the server chassis, and the second manifold liquid return hose may be connected to a second lateral side of the second liquid return manifold and extends rearward along the second lateral side of the server chassis.

Some embodiments provide a method of using the apparatus according to the embodiments herein. The method comprises connecting the first adapter bracket to one or more of the cold plates in a rear lateral row of processing unit assemblies, disconnecting the repositionable manifold from the operative position, moving the disconnected repositionable manifold rearward from the operative position to the service position to allow access to the plurality of components on the system board (that are forward of the rear lateral row of processing unit assemblies) without disconnecting any of the first plurality of flexible manifold hoses, temporarily securing or fastening the repositionable manifold to the first adapter bracket with the repositionable manifold in the service position, and performing the service operation on any one or more of the plurality of components on the system board while the repositionable manifold is temporarily secured or fastened to the first adapter bracket. In one option, the operation of moving the disconnected repositionable manifold assembly rearward from the operative position to the service position includes rotating the repositionable manifold assembly around a lateral axis.

### Repositionable Cold Plate for Improved Serviceability of a Server

Some embodiments provide an apparatus comprising a server chassis containing a lateral row of processing unit assemblies secured to a system board, wherein each processing unit assembly includes a processing unit and a cold plate that is selectively securable in thermal communication with the processing unit. The apparatus further comprises a manifold assembly secured in the server chassis forward of the lateral row of processing unit assemblies and including a rigid manifold bracket, a liquid supply manifold secured to the rigid manifold bracket, and a liquid return manifold secured to the first rigid manifold bracket. Still further, the apparatus comprises a plurality of flexible manifold hoses connected to the manifold assembly and extending rearward from the manifold assembly, wherein the plurality of flexible manifold hoses include a manifold liquid supply hose connected to an inlet to the liquid supply manifold, a manifold liquid return hose connected to an outlet from the liquid return manifold and, for each cold plate in the lateral row, a cold plate liquid supply hose connected from an outlet of the liquid supply manifold to an inlet to the cold plate and a cold plate liquid return hose connected from an outlet of the cold plate to an inlet of the liquid return manifold. Furthermore, each cold plate is independently selectively securable to the rigid manifold bracket to provide access to a processing unit in the same processing unit assembly as the cold plate.

In some embodiments, the server chassis may contain one or more lateral rows of processing units assemblies and one or more manifold assemblies, where each manifold assembly is provided to support cooling of processing units within one of the lateral rows. For example, a server chassis having two lateral rows of processing unit assemblies may have two manifold assemblies, where each manifold assembly is positioned forward of the lateral of processing units assemblies to which its cold plate liquid supply hoses and cold plate liquid return hoses are connected. In one specific example, the server chassis may have a front lateral row of processing unit assemblies, a rear lateral row of processing unit assemblies, a stationary manifold assembly for providing cooling liquid to and from the cold plates in the front lateral row of processing unit assemblies, and a repositionable manifold assembly for providing cooling liquid to and from the cold plates in the rear lateral row of processing unit assemblies. Accordingly, each cold plate in the front lateral row is independently selectively securable to the rigid manifold bracket of the stationary (front) manifold assembly to provide access to a processing unit in the front lateral row and/or each cold plate in the rear lateral row is independently selectively securable to the rigid manifold bracket of the repositionable (rear) manifold assembly to provide access to a processing unit in the rear lateral row. Furthermore, the server chassis may include any number of lateral rows of processing unit assemblies and an equal number of manifold assemblies for use in the same or similar manner as described herein.

In some embodiments, the lateral row of processing unit assemblies may be a front row of processing unit assemblies in an apparatus having both front and rear lateral rows of processing unit assemblies. However, in other embodiments, the manifold assembly may be beneficial to provide access to the processing units in the lateral row of processing unit assemblies regardless of the configuration of other components on the system board. The system board is a printed circuit board that supports the operation of the processing unit assemblies within the server. For example, the system board may provide power distribution, memory, data storage, network interfaces, and/or system management available to the processing units.

The processing unit within each processing unit assembly may be a central processing unit (CPU), a graphics processing unit (GPU) or other type of high performance processing unit. In one option, each processing unit is a graphics processing unit that is suitable for performing artificial intelligence models. Some servers may have as many as four graphics processing units positioned side-by-side in the lateral row of processing unit assemblies.

The cold plate within each processing unit assembly is a component that is used to manage the heat generated by a high-performance processing unit within the same processing unit assembly. The cold plate typically includes a metal plate, often made of copper or aluminum, which offers high thermal conductivity. The plate interfaces directly with the processing unit, such as a heat spreader secured to the processing unit, ensuring efficient heat transfer from the processing unit to the cold plate. Internally, the cold plate may include channels or grooves that allow a cooling liquid (i.e., “coolant”) to flow evenly through the plate. As the cooling liquid absorbs heat from the CPU, the circulating cooling liquid carries the heat away. The surface of the cold plate may be machined to achieve a flat and smooth contact area for engaging the processing unit, often accompanied by a layer of thermal paste that is applied to eliminate air gaps and enhance thermal conductivity. An external source of the cooling fluid may include pumps that ensure the cooling liquid continuously circulates through the cold plate to maintain a consistent or suitable operating temperature of the processing unit.

In some embodiments, the plurality of flexible manifold hoses may be made from a flexible polymer material that is compatible with the coolant. A preferred coolant includes water, such as a deionized water, but the coolant may include a mixture of water and a glycol composition, such as ethylene glycol or propylene glycol. However, the coolant may further include a synthetic mineral oil or dielectric fluid. Non-limiting examples of the flexible polymer material may include a flexible poly vinyl chloride (PVC) or an ethylene propylene diene monomer (EPDM) rubber.

In some embodiments, for each cold plate in the lateral row of processing unit assemblies, the cold plate includes a barbed liquid inlet coupling that is connected to one of the cold plate liquid supply hoses and a barbed liquid outlet coupling that is connected to one of the cold plate liquid return hoses. Optionally, the apparatus may include a plurality of hose clamps, wherein, for each cold plate liquid supply hose, one of the hose clamps secures an end of the cold plate liquid supply hose to one of the barbed liquid inlet couplings, and wherein, for each cold plate liquid return hose, one of the hose clamps secures an end of the cold plate liquid return hose to one of the barbed liquid outlet couplings. Some embodiments may further include, for each cold plate in the lateral row of processing unit assemblies, a barbed liquid outlet coupling of the liquid supply manifold that is connected to an opposing end of the cold plate liquid supply hose and a barbed liquid inlet coupling of the liquid return manifold that is connected to an opposing end of the cold plate liquid return hose. Optionally, one of the hose clamps secures the opposing end of the cold plate liquid supply hose to the barbed liquid outlet coupling and another of the hose clamps secures the opposing end of the cold plate liquid return hose to the barbed liquid inlet coupling. The combination of the barbed couplings and the hose clamps provide a reliable seal that is unlikely to leak and may be used in the various embodiments because there is no need to ever disconnect any of the hoses from any of the cold plates. Accordingly, embodiments provide the technical benefit of providing access and serviceability to components on the system board using a highly reliable hose connection and a manifold/hose configuration that avoids any disconnection of the hoses in the liquid distribution system.

Some embodiments of the apparatus further comprise a service bracket (a second adapter bracket) having a first arm selectively securable to the cold plate of any one of the processing unit assemblies and a second arm selectively securable to the rigid manifold bracket of the manifold assembly. In one option, the first arm may be perpendicular to the second arm. In another option, the rigid manifold bracket may include a plurality of connectors, where each connector is aligned with one of the cold plates in the lateral row, and the second arm of the service bracket is selectively securable to any one of the plurality of connectors. In this manner, the service bracket may be used to secure any one of the cold plates in the lateral row to the rigid manifold bracket in a service position that is aligned with the operative position of the cold plate. So, for each processing unit assembly, the cold plate is moveable from an operative position selectively secured in thermal communication with the processing unit to a service position selectively secured to the rigid manifold bracket to provide physical access to the processing unit with the first arm of the service bracket selectively secured to the cold plate and the second arm of the service bracket selectively secured to the connector of the rigid manifold bracket aligned with the cold plate.

In some embodiments, the cold plate of each processing unit assembly is moveable between the operative position and the service position without disconnecting any of the plurality of flexible manifold hoses. Optionally, the cold plate of each processing unit assembly may be moveable between the operative position and the service position without moving any other cold plate in the lateral row of processing unit assemblies. Furthermore, the lateral row of processing unit assemblies may include as many as four processing unit assemblies positioned side-by-side. As previously described, these embodiments are compatible with the use of barbed liquid inlet couplings and barbed liquid outlet coupling on the cold plates and the liquid supply and return manifolds. Flexible hoses may be coupled to the barbed couplings using hose clamps.

In some embodiments, the manifold assembly is secured at a higher elevation within the server chassis than an operative position of the processing unit assemblies. In one option, the cold plate is rotated around a lateral axis as it is moved between the operative position and the service position. For example, the cold plate may be rotated about 90 degrees around the lateral axis between the operative position and the service position. Furthermore, the manifold assembly at a higher elevation than the operative position of the cold plate, the cold plate may be elevated as it is being rotated toward the service position. Furthermore, the rigid manifold bracket of the manifold assembly may be above the liquid supply manifold and the liquid return manifold, and the liquid supply manifold and the liquid return manifold may each have a plurality of barbed couplings that are downward directed.

In some embodiments, each cold plate may have a top plate including two guide holes and a threaded hole, and the first arm of the service bracket may include two guide pins and a through hole. Accordingly, the first arm of the service bracket may be selectively securable to the cold plate of any one of the processing unit assemblies with the two guide pins inserted into the two guide holes and a screw passed through the through hole and threaded into the threaded hole. In one option, the rigid manifold bracket may include, for each of the cold plates in the lateral row, two guide holes and a threaded hole aligned with the cold plate, and the second arm of the service bracket may include two guide pins and a through hole. Accordingly, the second arm of the service bracket may be selectively securable to the rigid manifold bracket with the two guide pins inserted into the two guide holes in the rigid manifold bracket and a screw passed through the through hole and threaded into the threaded hole of the rigid manifold bracket. In a further option, the two guide pins on the first arm of the service bracket may be arranged in a different pattern than the two guide pins on the second arm of the service bracket to prevent the first arm from being misconnected to the rigid manifold bracket. In other words, the service bracket may have a preferred orientation with respect to the cold plate and the rigid manifold bracket and the unique guide pin arrangements on the first and second arms may limit the use of the service bracket to that preferred orientation.

In some embodiments, the rigid manifold bracket may have a first lateral end secured to a first lateral side of the server chassis and the second lateral end secured to a second lateral side of the server chassis. The manifold assembly may be secured to the server chassis in a temporary or permanent manner.

In some embodiments, the manifold liquid supply hose and the manifold liquid return hose extend rearward from the manifold assembly and out the rear of the server chassis without extending over any of the processing unit assemblies. For example, the first liquid supply hose may be connected to the liquid supply manifold along a first lateral side of the manifold assembly and extend rearward along the first lateral side of the server chassis, and the first liquid return hose may be connected to the liquid return manifold along a second lateral side of the manifold assembly and extend rearward along the second lateral side of the server chassis.

Some embodiments provide a method of using the apparatus of various embodiments. The method comprises unsecuring, for a selected one of the processing unit assemblies, the cold plate that is in an operative position in thermal communication with the processing unit, securing the first arm of the service bracket to the cold plate, moving the cold plate that is secured to the service bracket upward and forward, and securing the second arm of the service bracket to the rigid manifold bracket to hold the cold plate in a service position that does not interfere with access to the processing unit. In one option, moving the cold plate upward and forward includes rotating the cold plate around a lateral axis. The extent of rotation is not limited but may be about 90 degrees. For example, the operative position may be horizontal in the server chassis and the service position may be vertical in the server chassis.

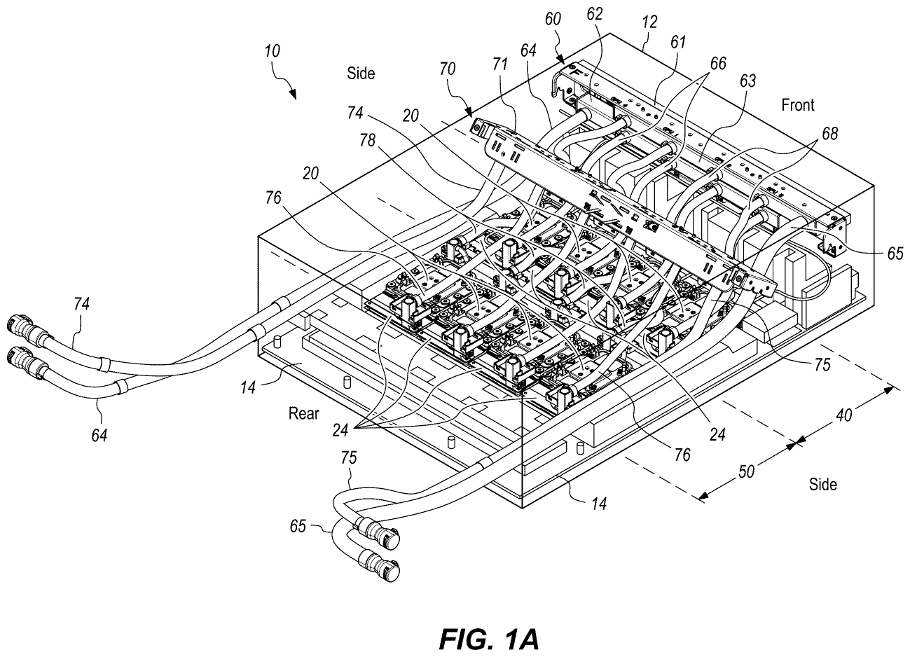

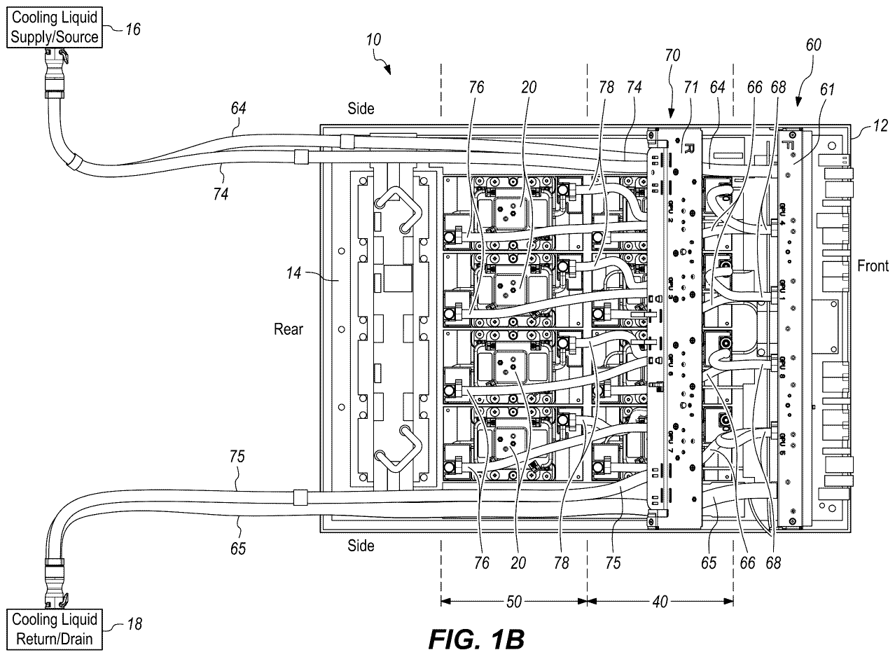

FIG. 1A is a perspective view of a server 10 having a server chassis 12 including a “Front” end, “Rear” end, two opposing lateral “Sides”, base (not labeled) and top (not labeled). The ends, sides, top and base of the server chassis 12 are shown to be transparent for the purpose of illustration so that the components within the server chassis 12 may be seen.

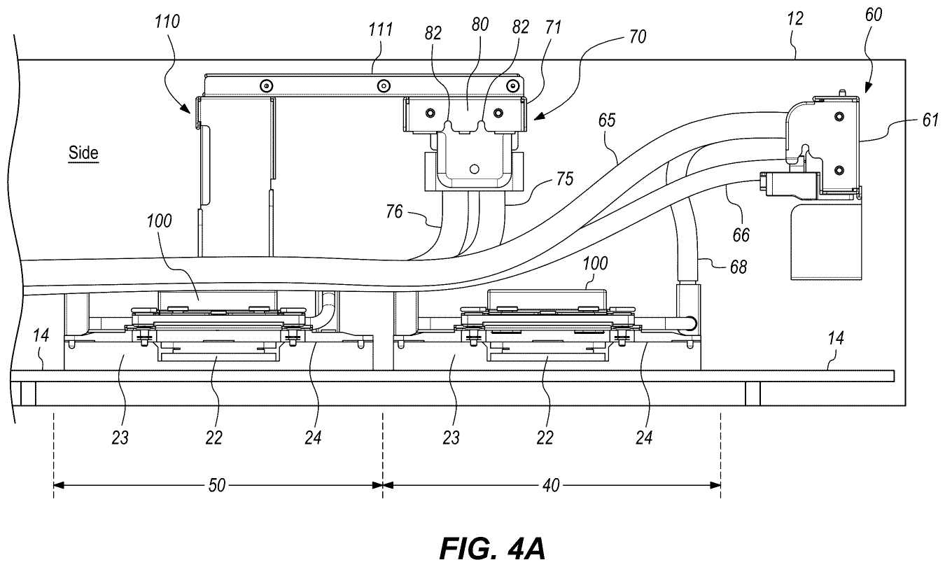

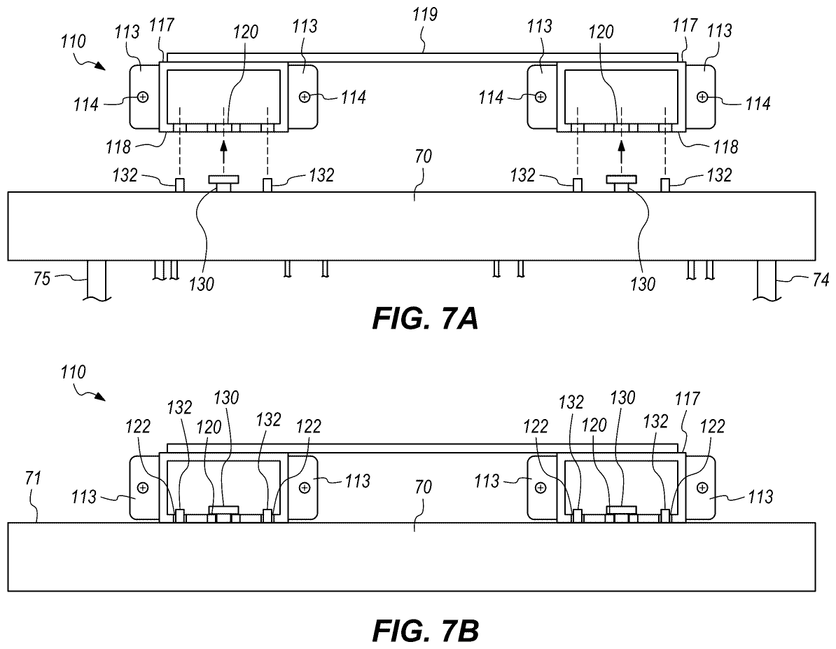

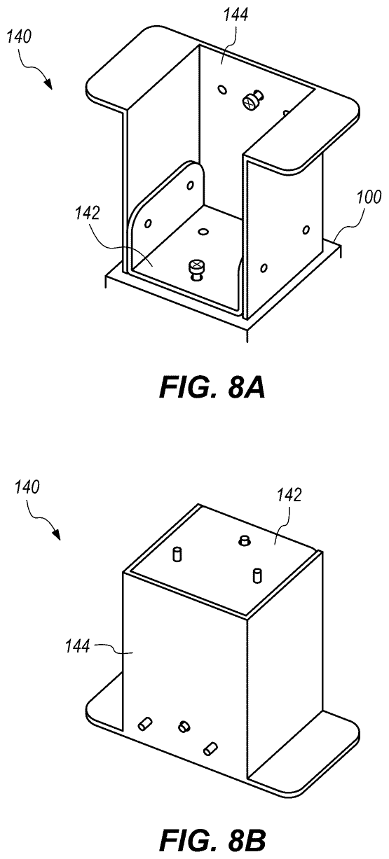

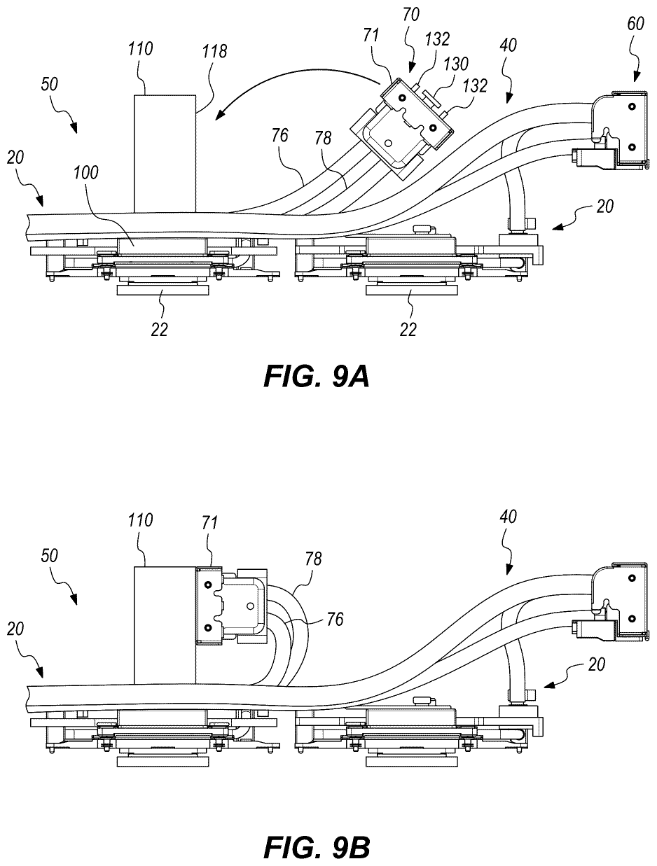

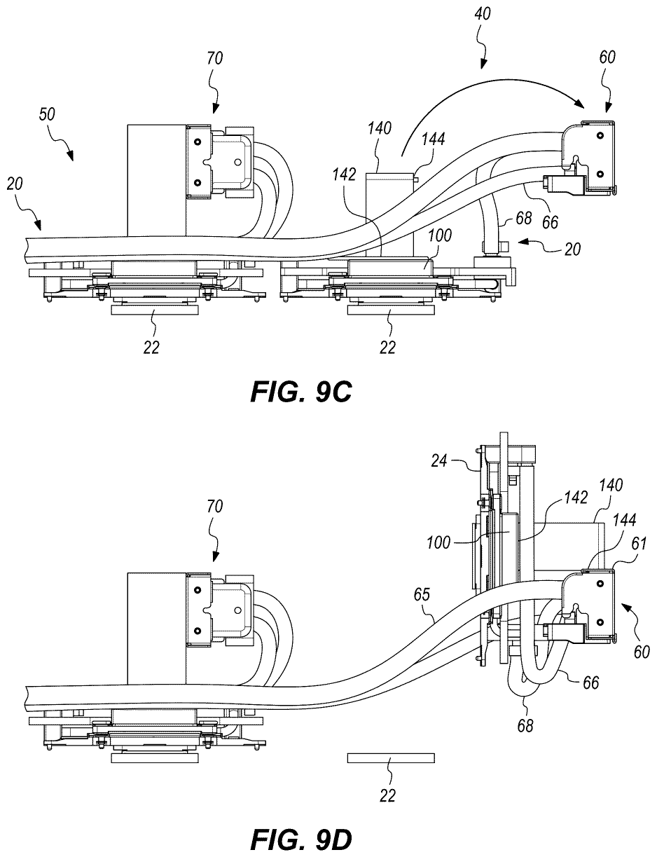

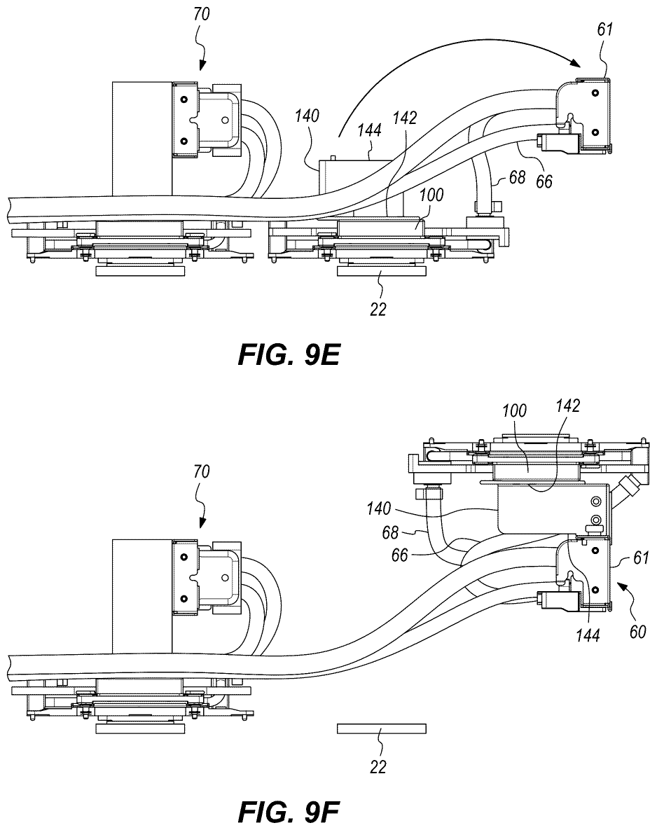

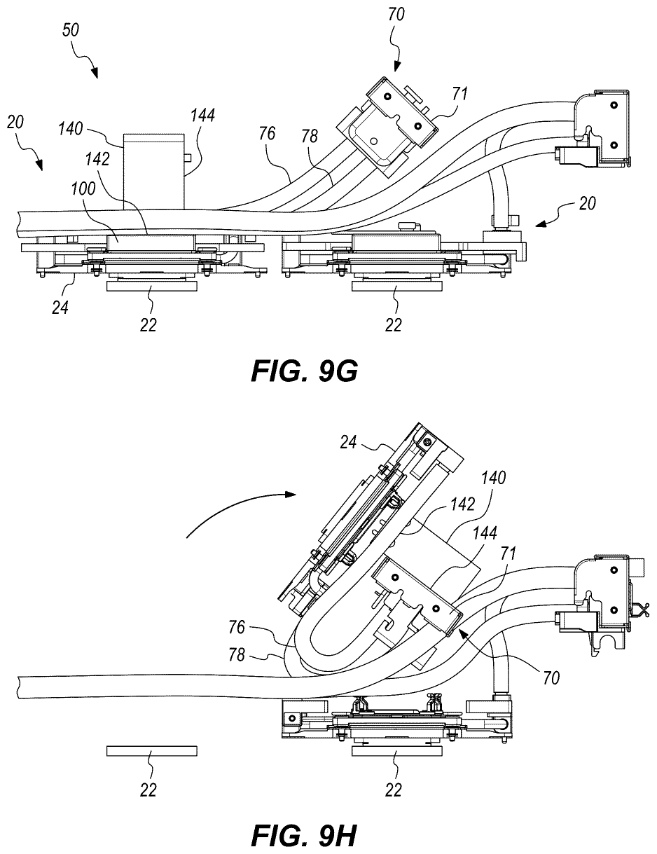

The server 10 includes a system board 14 supporting four (4) processing unit assemblies 20 arranged in a front lateral row 40 and four (4) processing unit assemblies 20 arranged in a rear lateral row 50. Each processing unit assembly 20 includes a processing unit 22 (not shown; but see FIG. 4A) and a cold plate 24 in thermal communication with the processing unit. The processing unit is received in a socket mounted to the system board and the cold plate 24 is positioned over the top of the processing unit (see FIG. 4A). While embodiments provide for the serviceability of the processing unit(s), that serviceability is brought about by the configuration of the liquid cooling system and certain adapter brackets that engage with components of the liquid cooling system. So, the processing units are shown for context in FIGS. 4A and 9A-H, but the discussion of the Figures is primarily directed to providing access to the processing units.

A stationary (front) manifold assembly 60 is secured within the server chassis 12 for supplying a cooling liquid to the four processing unit assemblies 20 in the front lateral row 40 and a repositionable (rear) manifold assembly 70 is secured within the server chassis 12 for supplying a cooling liquid to the four processing unit assemblies 20 in the rear lateral row 50. For example, the manifold assemblies 60, 70 may be connected to the two opposing sides of the server chassis 12.

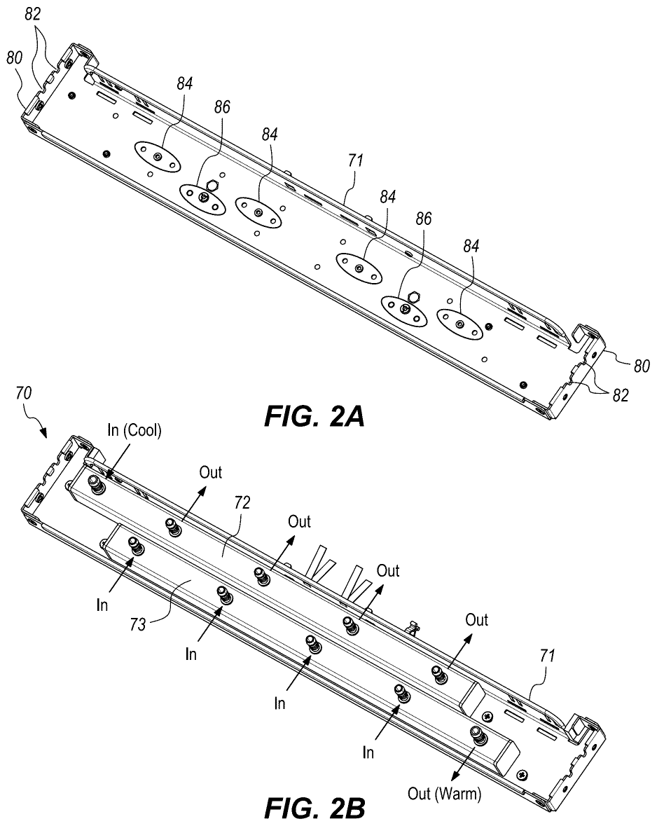

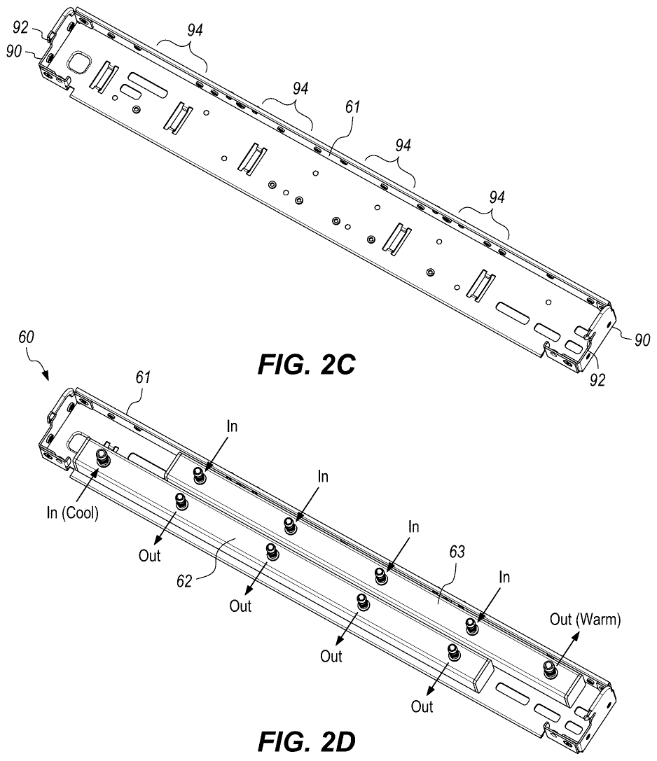

The repositionable manifold assembly 70 includes a first rigid manifold bracket 71, a first liquid supply manifold 72 (not shown; but see FIG. 2B) secured to the first rigid manifold bracket 71, and a first liquid return manifold 73 (not shown; but see FIG. 2B) secured to the first rigid manifold bracket. A first plurality of flexible manifold hoses are connected to the repositionable manifold assembly 70 and extend rearward from the repositionable manifold assembly 70. The first plurality of flexible manifold hoses includes a first manifold liquid supply hose 74 connected to an inlet to the first liquid supply manifold 72, a first manifold liquid return hose 75 connected to an outlet from the first liquid return manifold 73 and, for each cold plate 20 in the rear lateral row 50, a cold plate liquid supply hose 76 (only two are labeled) connected from an outlet of the first liquid supply manifold 72 to an inlet to the cold plate 20 and a cold plate liquid return hose 78 (only two are labeled) connected from an outlet of the cold plate 20 to an inlet of the first liquid return manifold 73. Furthermore, the first repositionable manifold assembly 70 is selectively securable in an operative position (as shown in FIG. 1A) forward of the rear lateral row 50 of processing unit assemblies 20 and extends laterally over a plurality of components on the system board 14. In this illustration, the plurality of components are the processing unit assemblies 20 in the front lateral row 40. The first repositionable manifold assembly 70 is also selectively securable in a service position rearward of the processing unit assemblies 20 in the front lateral row 40 (i.e., the plurality of components) to enable a service operation on any one or more of the plurality of components without disconnecting any of the first plurality of flexible manifold hoses 74, 75, 76, 78 (10 total hoses shown).

The stationary manifold assembly 60 is secured in the server chassis 12 forward of the front lateral row 40 of processing unit assemblies 20 and includes a rigid manifold bracket 61, a liquid supply manifold 62 secured to the rigid manifold bracket 61, and a liquid return manifold 63 secured to the first rigid manifold bracket 61. A plurality of flexible manifold hoses are connected to the stationary manifold assembly 60 and extend rearward from the stationary manifold assembly 60. The plurality of flexible manifold hoses include a manifold liquid supply hose 64 connected to an inlet to the liquid supply manifold 62, a manifold liquid return hose 65 connected to an outlet from the liquid return manifold 63 and, for each cold plate 20 in the front lateral row 40, a cold plate liquid supply hose 66 (only two labeled) connected from an outlet of the liquid supply manifold 62 to an inlet to the cold plate 20 and a cold plate liquid return hose 68 (only two labeled) connected from an outlet of the cold plate 20 to an inlet of the liquid return manifold 63.

FIG. 1B is a top (plan) view of the server of FIG. 1A. The content of FIG. 1B is substantially the same as that of FIG. 1A, except that some components are easier to view and some components are more difficult to view. For example, the configuration or layout of the flexible hoses is easier to see in FIG. 1B. However, the liquid supply and return manifolds 62, 63 of the stationary manifold assembly 60, as well as the four (4) processing unit assemblies 20 arranged in a front lateral row 40, are easier to see in FIG. 1A.

In reference to FIG. 1B, it can be seen that the first manifold liquid supply hose 74 is connected from a cooling liquid supply/source 16 to an inlet to the liquid supply manifold of the repositionable manifold assembly 70 and that the second manifold liquid supply hose 64 is connected from the cooling liquid supply/source 16 to an inlet to the liquid supply manifold of the stationary manifold assembly 60. Notably, both of the manifold liquid supply hoses 64, 74 are positioned along one lateral side of the server chassis 12 and do not obstruct access to any of the processing unit assemblies 20.

In further reference to FIG. 1B, it can be seen that the first manifold liquid return hose 75 is connected from an outlet of the liquid return manifold of the repositionable manifold assembly 70 to a cooling liquid return/drain 18 and that the second manifold liquid return hose 65 is connected from an outlet of the liquid return manifold of the stationary manifold assembly 60 to the cooling liquid return/drain 18 and. Notably, both of the manifold liquid return hoses 65, 75 are positioned along another lateral side of the server chassis 12 and do not obstruct access to any of the processing unit assemblies 20.

Each of the plurality of flexible manifold hoses connected to the repositionable manifold assembly 70 extend rearward from the repositionable manifold assembly 70. This includes the first manifold liquid supply hose 74, the first manifold liquid return hose 75, and, for each cold plate in the rear lateral row 50, the cold plate liquid supply hose 76 and the cold plate liquid return hose 78. Notice that each processing unit assembly 20 in the rear lateral row 50 has a cold plate connected to one cold plate liquid supply hose 76 and one cold plate liquid return hose 78, where both of these hoses 76, 78 are routed over the processing unit assembly 20 and do not pass over or obstruct access to a laterally adjacent processing unit assembly in the same lateral row.

Similarly, each of the plurality of flexible manifold hoses connected to the stationary manifold assembly 60 extend rearward from the stationary manifold assembly 60. This includes the second manifold liquid supply hose 64, the second manifold liquid return hose 65, and, for each cold plate in the front lateral row 40, the cold plate liquid supply hose 66 and the cold plate liquid return hose 68. Notice that each processing unit assembly 20 in the front lateral row 40 has a cold plate connected to one cold plate liquid supply hose 66 and one cold plate liquid return hose 68, where both of these hoses 66, 68 are routed over the processing unit assembly 20 and do not pass over or obstruct access to a laterally adjacent processing unit assembly.

FIG. 1B also clearly shows that the repositionable manifold assembly 70 is positioned in an operative position that is directly over the top of the processing unit assemblies 20 in the front lateral row 40 and obstructs access to those four processing unit assemblies 20. Conversely, the stationary manifold assembly 60 is positioned in an operative position that does not obstruct access to any of the processing assemblies 20.

FIGS. 2A-B are bottom perspective views of the rigid manifold bracket 71 and the repositionable (rear) manifold assembly 70 including the rigid manifold bracket 71, a liquid supply manifold 72, and a liquid return manifold 73. In reference to FIG. 2A, the rigid manifold bracket 71 has two ends 80 each with a pair of slots 82 to engage a pair of T-pins in a side wall of the server chassis 12 (see FIGS. 1A-B). The rigid manifold bracket 71 further includes four sets of connectors 84 for temporarily connecting a second (service) bracket and two sets of connectors 86 for temporarily connecting a handle bracket, as later described. However, the connectors 84, 86 are accessed and utilized from the top side of the rigid manifold bracket 71.

In reference to FIG. 2B, the liquid supply manifold 72 and the liquid return manifold 73 are shown secured to the bottom surface of the rigid manifold bracket 71. The manifolds 72, 73 have similar construction including a hollow interior passageway for carrying liquid and five barbed liquid couplings. However, the liquid supply manifold 72 has one inlet for receiving a cooling liquid and four outlets for supplying the cooling liquid to any one of the four cold plates in the rear lateral row of processing unit assemblies. Conversely, the liquid return manifold 73 has four inlets for receiving a warmed cooling liquid from the four cold plates in the rear lateral row of processing unit assemblies and one outlet for returning warmed cooling liquid.

FIGS. 2C-D are bottom perspective views of the rigid manifold bracket 61 and the stationary (front) manifold assembly 60 including the rigid manifold bracket 61, the liquid supply manifold 62, and the liquid return manifold 63.

In reference to FIG. 2C, the rigid manifold bracket 61 has two ends 90 each with one or more connectors 92 for connecting the bracket to a side wall of the server chassis 12 (see FIGS. 1A-B). The rigid manifold bracket 61 further includes four sets of connectors 94 (of the same/similar configuration as the connectors 84 shown in FIG. 2A) for temporarily connecting a second (service) bracket. However, the connectors 94 are accessed and utilized from the top side of the rigid manifold bracket 71.

In reference to FIG. 2D, the liquid supply manifold 62 and the liquid return manifold 63 are shown secured to the bottom surface of the rigid manifold bracket 61. The manifolds 62, 63 have similar construction including a hollow interior passageway for carrying liquid and five barbed liquid couplings. However, the liquid supply manifold 62 has one inlet for receiving a cooling liquid and four outlets for supplying the cooling liquid to any one of the four cold plates in the rear lateral row of processing unit assemblies. Conversely, the liquid return manifold 63 has four inlets for receiving a warmed cooling liquid from the four cold plates in the rear lateral row of processing unit assemblies and one outlet for returning warmed cooling liquid.

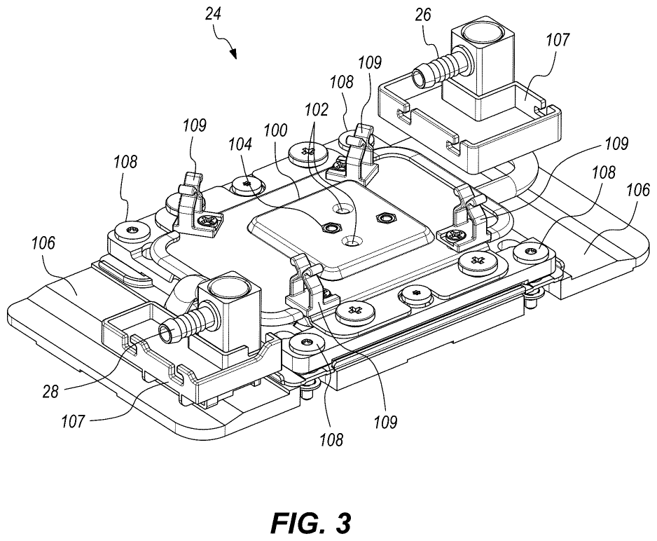

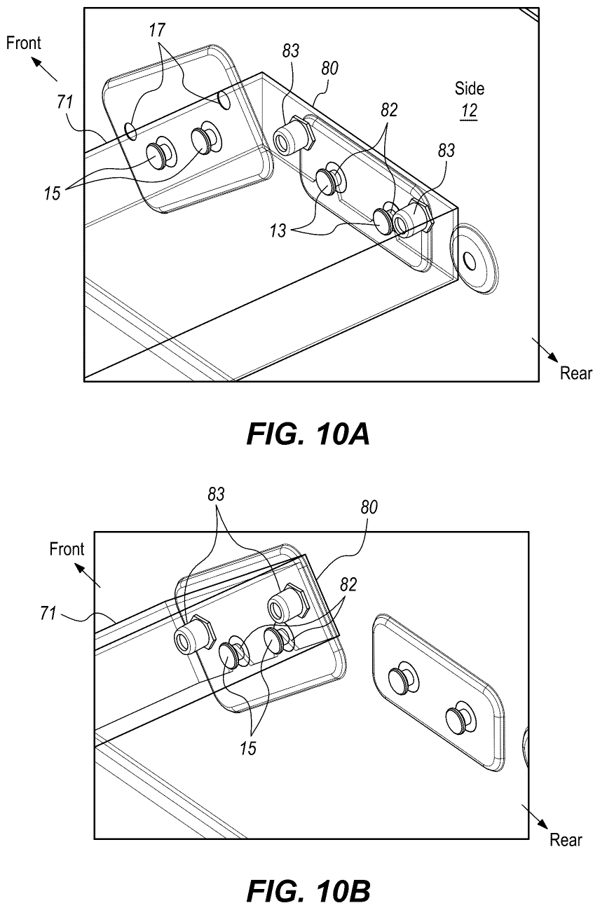

FIG. 3 is a perspective view of a cold plate 24 including a cooling liquid inlet 26, a cooling liquid outlet 28 and a top plate 100. A flow path from the cooling liquid inlet 26 through the cold plate 24 to the cooling liquid outlet 28 is shown in greater detail in FIG. 11. The top plate 100 includes a connector consisting of a pair of guide or alignment holes 102 and a threaded hole 104 for connecting with an adapter bracket (not shown).

The cold plate 24 include a plate 106 that has a high thermal conductivity for transferring heat from a processing unit (not shown) into the cooling liquid that passes through the plate 106. A set of cap screws 108 are used to secure the cold plate 24 to a socket on the system board (not shown) for thermal communication with the processing unit. Still further, the cold plate 24 is shown with optional drip trays 107 for catching any liquid that might leak from the barbed couplings 26, 28. A sensor cable (not shown) may be secured into slots in the top edge of the drip trays 10 to trigger an alert to the presence of liquid in the drip tray. Cable sensor clips 109 may be provided either to keep the sensor cable confined within the bounds of the cold tray 24 so as not to obstruct a service operation involving a laterally adjacent cold plate or to retain the sensor cable of a laterally adjacent cold plate during the service operation.

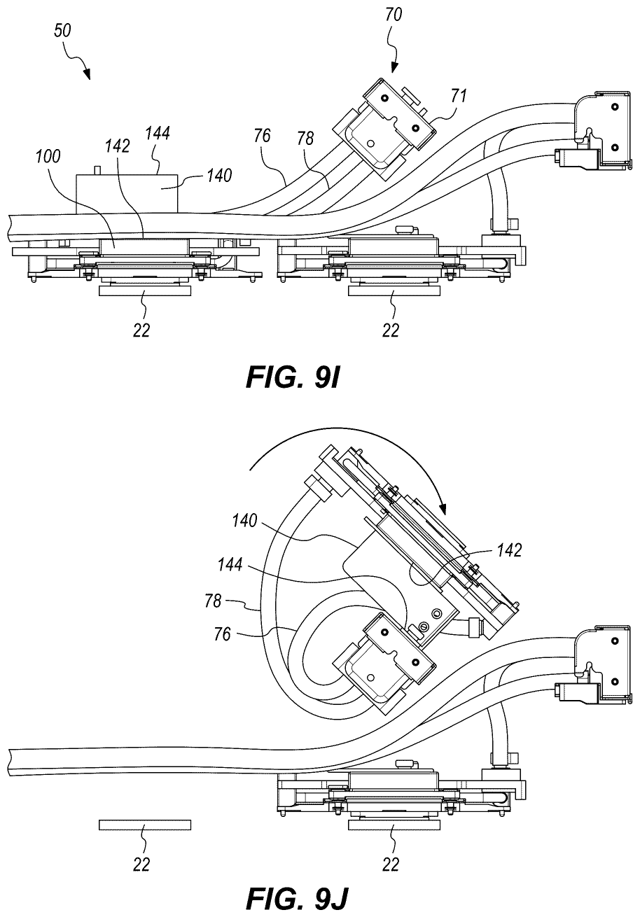

FIGS. 4A-B are partial side and perspective views showing the repositionable manifold assembly 70 secured in a shipping position using a first (shipping) adapter bracket 110 and a pair of handle brackets 111. The first (shipping) adapter bracket 110 is secured to the top plates 100 of the cold plates 24 in the rear lateral row 50. The pair of handle brackets 111 (only one shown; see FIG. 4B) are connected between the first (shipping) adapter bracket 110 and the rigid manifold bracket 71 of the repositionable manifold assembly 70. These connections prevent the repositionable manifold assembly 70 from moving and/or being damaged during shipping of the server chassis 12. The two slots 82 formed in the end 80 of the rigid manifold bracket 71 may also assist in stabilizing the repositionable manifold assembly 70 by engaging T-pins (not shown; see FIG. 10A) that extend inward from the side walls of the server chassis 12.

In reference to the side view of FIG. 4A, the system board 12 is supported in the base or bottom of the server chassis 12 on a set of standoffs. A socket 23 secured to the system board 12 for receiving and supporting the operation of a processing unit 22. The cold plate 24 then contacts the top face of the processing unit 22 in order to absorb heat that is generated by the operations of the processing unit 22.

In reference to the perspective view of FIG. 4A, the two handle brackets 111 are shown having a first end connected to the repositionable manifold assembly 70 and a second end connected to the first (shipping) adapter bracket 110. For the connection between the first (shipping) adapter bracket 110 and the top plate 100 of the cold plates, two of the four connections can be seen to include guide pins received in the guide holes 102 (see also FIG. 3) in the top plate 100 and a cap screw received in the threaded hole 104 (see also FIG. 3).

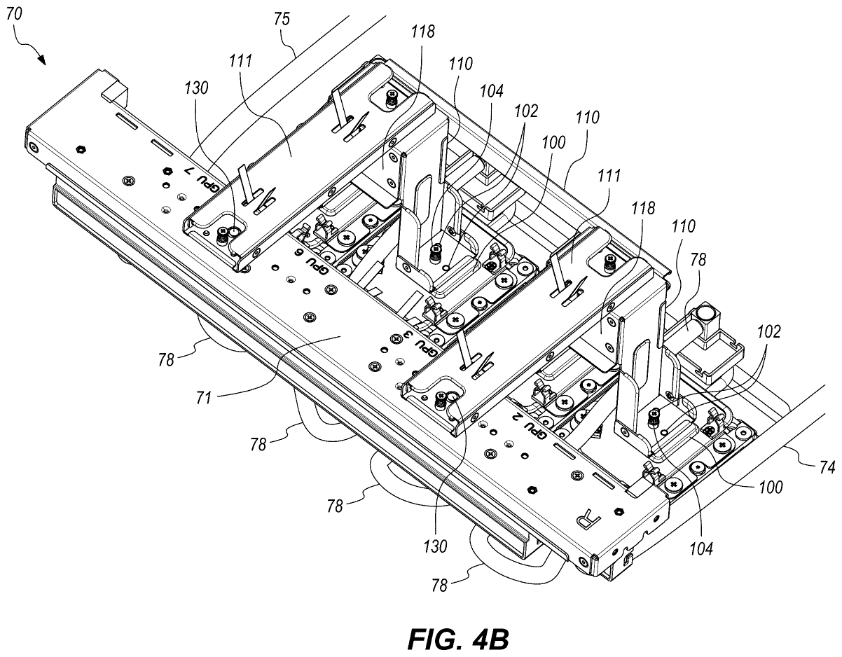

FIGS. 5A-B are perspective views of the first adapter bracket 110 with and without the pair of handle brackets 111. In FIG. 5A, each end of the handle brackets 111 include connectors consisting of a pair of guide pins or guide holes on opposing sides of a cap screw 112. The first adapter bracket 110 includes four feet or bases 113, each base 113 including connectors consisting of a pair of guide pins on opposing sides of a cap screw 114. The relative positioning of the cap screw 114 and the guide pins 116 mate with the threaded hole 104 and guide holes 102 in the top plates 100. Two connection faces 118 are therefore supported above the processing unit assemblies in the rear lateral row 50 and face forward toward the repositionable manifold assembly 70 (see FIG. 4B). In the embodiments shown, a pair of upstanding bracket members are secured together by a crossarm 119.

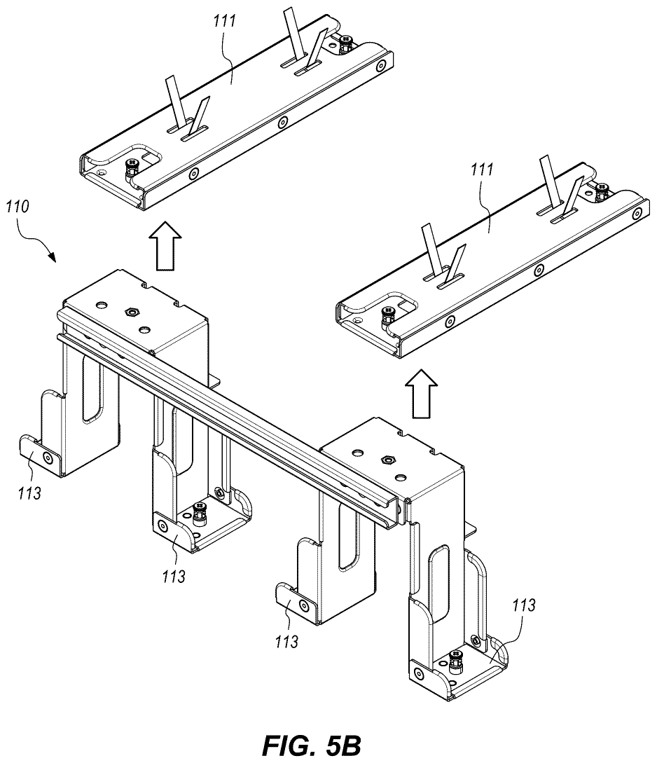

In reference to FIG. 5B, the handle brackets 111 have been separated from the first (shipping) adapter bracket 110. The first (shipping) adapter bracket 110 may be used for a secondary use (i.e., other than for shipping) to secure the repositionable manifold assembly 70 (not shown) in a service position (see FIGS. 7B and 9B-F).

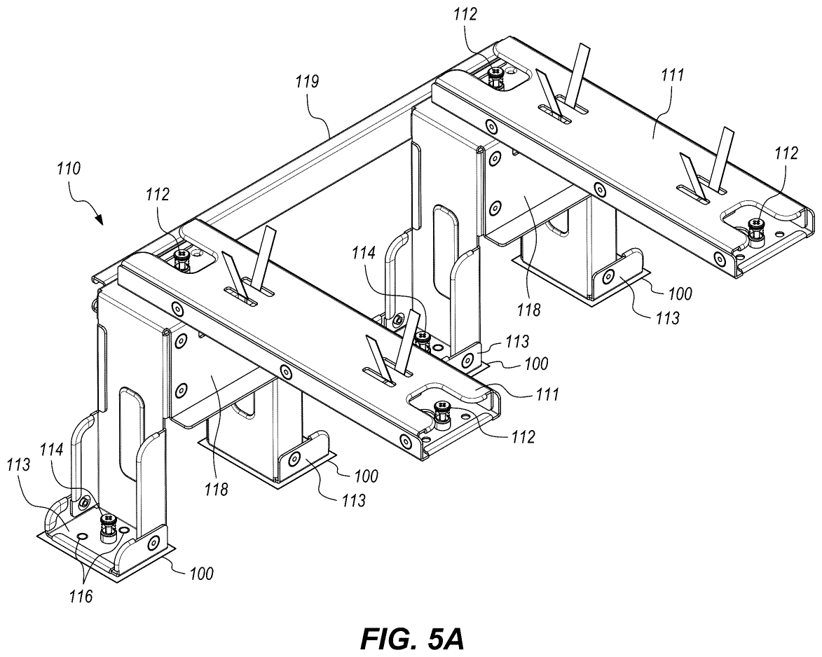

FIGS. 6A-B are back and front views of the first adapter bracket 110. The back view of FIG. 6A shows the first adapter bracket 110 having four bases 113 and each base 113 having a pair of guide pins 116 extending therefrom. Also, the two adapter bracket members 117 are secured together as a unit by the crossarm 119.

In reference to the front view of FIG. 6B, each adapter bracket member 117 includes a connection face 118 for temporarily securing the repositionable manifold assembly 70 in a service position (see FIGS. 7B and 9B-F). As shown, the connection face 118 may include a keyhole slot 120 and a pair of guide slots 122 that may temporarily secure a T-pin and pair of guide pins (not shown; but see FIGS. 7A-B) formed on the top of the repositionable manifold assembly 70.

FIG. 6B also shows the cap screws 114 and the guide pins 116 extending from each base 113 to connect with the threaded holes 104 and the guide holes 102 in the top plate 100, respectively. This is how the first adapter bracket 110 may be secured to the four top plates 100.

FIG. 7A-B are schematic top views of the first adapter bracket 110 and the repositionable manifold assembly 70 before and after forming a temporary connection that secures the repositionable manifold assembly 70 in a service position. In FIG. 7A, a pair of T-pins 130 and corresponding guide pins 132 are aligned with the keyhole slot 120 and the guide slots 122 (see also FIG. 6B) in the connections faces 118 of the first adapter bracket 110. In order for the repositionable manifold assembly 70 to be in this position with its top surface facing rearward toward the connection faces 118, the repositionable manifold assembly 70 must be moved rearward and rotated about a lateral axis. This is best seen in reference to FIGS. 9A-B.

In reference to FIG. 7B, the corresponding guide pins 132 have been received into the guide slots 122 and the pair of T-pins 130 have been received into the keyhole slot 120 (see also FIG. 6B) in the connections faces 118 of the first adapter bracket 110. Specifically, the T-pin 130 has a wide head and a narrow shaft connecting the head to the rigid manifold bracket 71. One the wide head of the T-pin 130 has passed through the wide portion of the keyhole slot 120, then the rigid manifold bracket 71 is moved downward (into the image of FIGS. 7A-B) so that the narrow shaft is seated in the narrow portion of the keyhole slot 120 and the wide head prevents the T-pin 130 from pulling out of the keyhole slot 120. This is the service position of the repositionable manifold assembly 70. In order to release the repositionable manifold assembly 70 from the service position, the repositionable manifold assembly 70 must be lifted to align the head of the T-pin 130 with the wide portion of the keyhole slot 120 and then pulling the head of the T-pin 130 out through the wide portion of the keyhole slot 120. The position of the T-pin 130 on the repositionable manifold assembly 70 can be seen in reference to FIG. 4B, wherein the head of the T-pin 130 is received in a relief hole into the handle bracket 111.

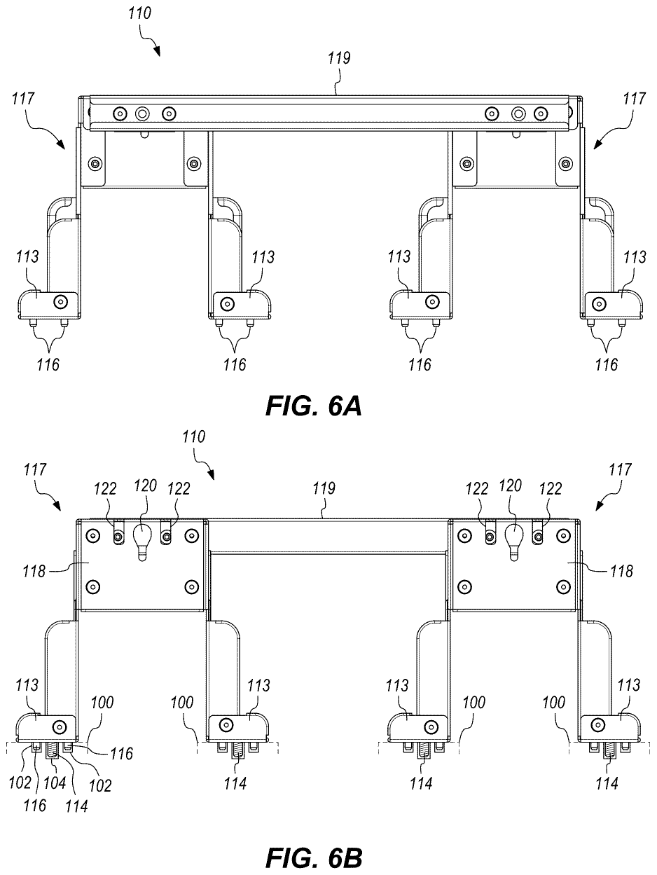

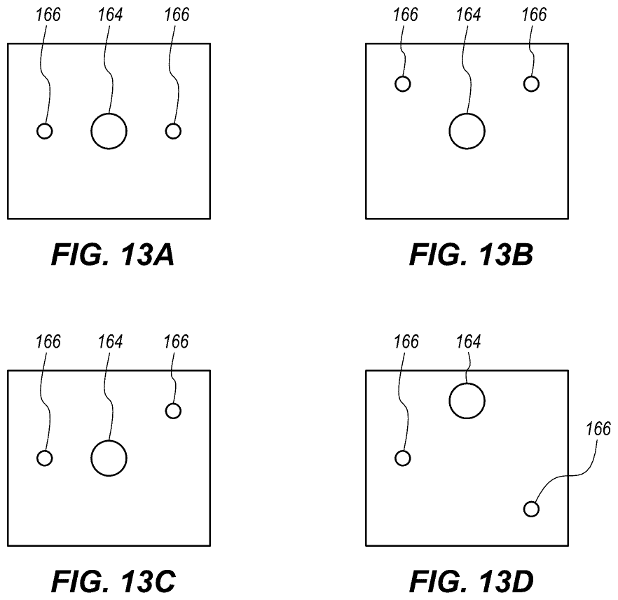

FIGS. 8A-B are upright and upside-down perspective views of a second (service) adapter bracket 140. The second adapter bracket b140 has a first arm or surface 142 selectively securable to the top plate 100 of any one of the processing unit assemblies 20 (not shown; see FIG. 1A) and a second arm or surface 144 selectively securable to the rigid manifold bracket 61, 71 of the manifold assembly 60, 70. In one option, the first arm 142 may be perpendicular to the second arm 144. In another option, the rigid manifold bracket 61, 71 may include a plurality of connectors 94, 84, where each connector 94, 84 is aligned (axially from the front to the rear) with one of the cold plates 24 in one of the lateral rows 40, 50, and the second arm 144 of the second adapter bracket 140 is selectively securable to any one of the plurality of connectors 94, 84. In this manner, the second adapter (service) bracket 140 may be used to secure any one of the cold plates in the lateral row to the rigid manifold bracket 61, 71 in a service position that is axially aligned with the operative position of the cold plate 24. The connectors on the first arm 142 may include a pair of guide pins and a cap screw and the connectors on the second arm 144 may also include a pair of guide pins and a cap screw. The configuration of the guide pins and cap screw of the first and second arms 142, 144 may be same, but are shown in two unique configurations that prevent the second adapter bracket 140 from being installed in an inverted position. In other words, a specific arm of the second adapter bracket 140 may only be connected to the top plate 100 and the other arm of the second adapter bracket 140 may only be connected to the manifold assembly 60, 70. This is discussed further in reference to FIGS. 13A-D. In another option, the second adapter bracket 140 may include a pair of side wings or handles 146 to assist the user lifting the second adapter bracket 140 with a cold plate 24 attached (see FIG. 9D).

FIG. 9A is a partial side view of the server of FIG. 1 with the first (shipping) adapter bracket 110 secured to the top plates 100 in the rear lateral row 50 of processing unit assemblies 20 as shown in FIGS. 4A-B except without the handle brackets. Accordingly, the connection faces 118 that include the keyhole slots 120 and guide slots 122 (see FIG. 6B) are facing forward toward the repositionable manifold assembly 70. Note the position of the T-pin 130 and guide pins 132 on the top of the rigid manifold bracket 71.

FIG. 9B is a partial side view as in FIG. 9A after the repositionable (rear) manifold assembly 70 has been temporarily connected to the first adapter bracket 110 to be secured in a service position. To reach the service position, the repositionable (rear) manifold assembly 70 is moved rearward and rotated (see the arrow) into a position aligned with the slots 118, 120 of the connector face 118 as shown in FIG. 7A. After subsequent connection as described in reference to FIG. 7B, the service position of FIG. 9B is achieved.

It is important to notice that the rearward rotational movement (or “rolling”) of the repositionable (rear) manifold assembly 70 from the operative position (FIG. 9A) to the service position (FIG. 9B) may only be accomplished because the plurality of hoses connected to the repositionable (rear) manifold assembly 70 are each flexible and extend rearward toward the rear of the server chassis 12. If any of the hoses connected to the repositionable (rear) manifold assembly 70 extended forward, then this movement may be impeded or prevented. It is also important to note that the cold plate liquid supply hoses 76, the cold plate liquid return hoses 78, the manifold liquid supply hose 74, and the manifold liquid return hose 75 are each flexed and drawn rearward to that they are no longer obstructing access to the top of the processing unit assemblies 20 in the front row 40.

FIG. 9C is a partial side view as in FIG. 9B with a second (service) adapter bracket 140 secured to a top plate 100 in the front lateral row 40 of processing unit assemblies 20. The access to secure the second adapter bracket 140 as shown is made possible by securing the repositionable manifold assembly 70 in the service position.

FIG. 9D is a partial side view as in FIG. 9C after the cold plate 24 in the front lateral row 40 of processing unit assemblies has been temporarily connected to the stationary (front) manifold assembly 60 to provide unobstructed access to the processing unit 22. For each processing unit assembly, the cold plate 24 is moveable from an operative position (FIG. 9C) selectively secured in thermal communication with the processing unit 22 to a service position (FIG. 9D) selectively secured to the rigid manifold bracket 61 to provide physical access to the processing unit 22 with the first arm 142 of the second adapter bracket 140 selectively secured to the top plate 100 and the second arm 144 of the second adapter bracket 140 selectively secured to the connector of the rigid manifold bracket 61 axially aligned with the cold plate 24.

Note that the second adapter bracket 140 is secured to a single cold plate 24 to gain unobstructed access to a single processing unit 22. The cold plate liquid supply hose 66 and the cold plate liquid return hose 68 are flexed and bent upward and remain out of the way for accessing the processing unit 22. Furthermore, as shown in FIG. 1B, the hoses 66, 68 for any adjacent processing unit assemblies 20 in the same lateral row 40 will not prevent the movement illustrated between FIG. 9C and FIG. 9D.

FIGS. 9E-F are partial side views as in FIGS. 9C-D using a different configuration of the second (service) adapter bracket 140 to secure the cold plate 24 in a different position while providing unobstructed access to the processing unit 22. Specifically, the second arm or surface 144 is oriented 180 degrees from that of the first arm or surface 142. Accordingly, when the cold plate 24 is lifted and rotated forward, the cold plate 24 is rotated 180 degrees (upside down) before the second adapter bracket 140 is in position for its connectors on the second arm or surface 144 to be aligned and secured to the top surface of the rigid manifold bracket 61 of the stationary manifold assembly 60. So, embodiments may position the cold plate 24 in a vertical service position/orientation (FIG. 9D), a horizontal service position/orientation (FIG. 9F), or other service position/orientation as will be readily apparent by changing the angle between the first and second arms or surfaces 142, 144 of the second adapter bracket 140.

FIGS. 9G-H are partial side views as in FIG. 9A except that the second (service) adapter bracket 140 is being used and the first adapter bracket 110 (FIG. 9A) is not used. Rather than moving the repositionable manifold assembly 70 using the first adapter bracket 110, FIGS. 9G-H use the second adapter bracket 140 secured to one of the cold plates 24 in the rear lateral row 50 of processing unit assemblies 20. The principle behind the movement of the cold plate 24 to a service position secured to the repositionable manifold assembly 70 is the same as the movement of the cold plate 24 to a service position secured to the stationary manifold assembly 60 as shown in reference to FIGS. 9C-F.

In reference to FIG. 9G, the first arm or surface 142 of second adapter bracket 140 has been secured to the top plate 100 one of the cold plates 24 in the rear lateral row 50 of processing unit assemblies 20. While the manifold assembly 70 is a repositionable manifold assembly, the repositionable manifold assembly 70 is not repositioned (remains in the operative position) to access and service a processing unit 22 in the rear lateral row 50.

In reference to FIG. 9H, the cold plate 24 from the rear lateral row 50 has been temporarily connected to the repositionable (rear) manifold assembly 70 to provide unobstructed access to the processing unit 22. For each processing unit assembly in the rear lateral row, the cold plate 24 is moveable from an operative position (FIG. 9G) selectively secured in thermal communication with the processing unit 22 to a service position (FIG. 9H) selectively secured to the rigid manifold bracket 71 to provide physical access to the processing unit 22 with the first arm 142 of the second adapter bracket 140 selectively secured to the top plate 100 and the second arm 144 of the second adapter bracket 140 selectively secured to the connector of the rigid manifold bracket 71 that is axially aligned with the cold plate 24.

Note that the second adapter bracket 140 is secured to a single cold plate 24 to gain unobstructed access to a single processing unit 22. The cold plate liquid supply hose 76 and the cold plate liquid return hose 78 are flexed and bent upward and remain out of the way for accessing the processing unit 22. Furthermore, as shown in FIG. 1B, the hoses 66, 68 for any adjacent processing unit assemblies 20 in the same lateral row 40 will not prevent the movement illustrated between FIG. 9G and FIG. 9H. Also note that any one or more of the cold plates 24 in the rear lateral row may be placed in the service position at the same time, but each cold plate 24 requires its own second adapter bracket 140 and is independently moved and secured to the rigid manifold bracket 71.

FIGS. 9I-J are partial side views as in FIGS. 9G-H using a different configuration of the second (service) adapter bracket 140 to secure the cold plate 24 in a different position while providing unobstructed access to the processing unit 22. Specifically, the second arm or surface 144 is oriented 180 degrees from that of the first arm or surface 142. Accordingly, when the cold plate 24 is lifted and rotated forward, the cold plate 24 is rotated 180+ degrees (upside down) before the second adapter bracket 140 is in position for its connectors on the second arm or surface 144 to be aligned and secured to the top surface of the rigid manifold bracket 71 of the repositionable manifold assembly 70. So, embodiments may position the cold plate 24 in a relatively vertical or rearward angled service position/orientation (FIG. 9H), a relatively horizontal or forward angled service position/orientation (FIG. 9J), or other service position/orientation as will be readily apparent by changing the angle between the first and second arms or surfaces 142, 144 of the second adapter bracket 140.

FIGS. 10A-B are partial perspective views of one side of the server chassis 12 including attachment points for securing the rigid mounting bracket 71 of the repositionable manifold assembly 70 in the shipping position (FIG. 10A) and the operative position (FIG. 10B), respectively.

In reference to FIG. 10A, the rigid mounting bracket 71 has the end 80 with two slots 82 and two threaded holes or nuts 83. The two slots 82 may engage two T-pins 13 with the same spacing. The rigid mounting bracket 71 of the repositionable manifold assembly 70 is held in this position by with the first (shipping) adapter bracket 110 and the handle bracket 111 as shown in FIGS. 4A-B.

In reference to FIG. 10B, the two slots 82 on the end 80 of the rigid mounting bracket 71 are now engaged with two T-pins 15 with the same spacing. However, the two T-pins 15 are positioned on the side of the server chassis 12 to define the operative position of the repositionable manifold assembly 70. The rigid mounting bracket 71 of the repositionable manifold assembly 70 is held in this position using a pair of screws (not shown) that are inserted from the outside of the server chassis 12 through the holes 17 (see FIG. 10A) and threaded into the two threaded holes or nuts 83 in the end 80 of the rigid mounting bracket 71. Accordingly, the repositionable manifold assembly 70 is secured held in the operative position but may be unsecured by removed two screws on each end 80 of the rigid mounting bracket 71.

FIG. 11 is a schematic diagram illustrating the hose connections to the cooling liquid inlet and outlet of the cold plate 24 and the pathway that the cooling liquid follows through the cold plate. A cooling liquid supply hose 76 is slid over the barbed inlet coupling 26 to establish fluid communication between the hose 76 and the barbed coupling 26. The barbs on the outer circumference of the of the barbed coupling 26 resist the hose 76 pulling off. However, an additional level of security against the hose 76 pulling off the barbed coupling 26 and/or against liquid leaking out of the connection formed by the hose 76 and the barbed coupling 26 may be provided by applying a hose clamp 150. A standard hose clamp 150 may include a band 152 that is placed around the end of the hose. The band 152 include a screw thread pattern and a worm gear or captive screw 154, such that turning the worm gear or captive screw 154 in a first rotational direction causes tightening of the band 152 around the hose 76 and loosening the worm gear or captive screw 154 in a second rotational direction causes loosening of the band 152 around the hose 76. The force of the band 152 may press the hose 76 against the barbs of the barbed coupling 26 to form a liquid tight connection with a high degree of reliability and security.

A cooling liquid return hose 75 is slid over the barbed inlet coupling 28 to establish fluid communication between the hose 75 and the barbed coupling 28. A hose clamp 150 may also be applied to this connection in the same manner as described for the cold plate inlet coupling 26.

With the hoses 76, 75 secured as shown, liquid from the manifold assembly may flow through the cooling liquid supply hose 76, the barbed inlet coupling 26, the main body of the cooling plate 24, the barbed outlet coupling 28 and the cooling liquid return hose 75. The fluid pathway through the main body of the cold plate 24 may be a serpentine pattern or other flow pattern but is represented as simplified flow path for purposes of the present disclosure.

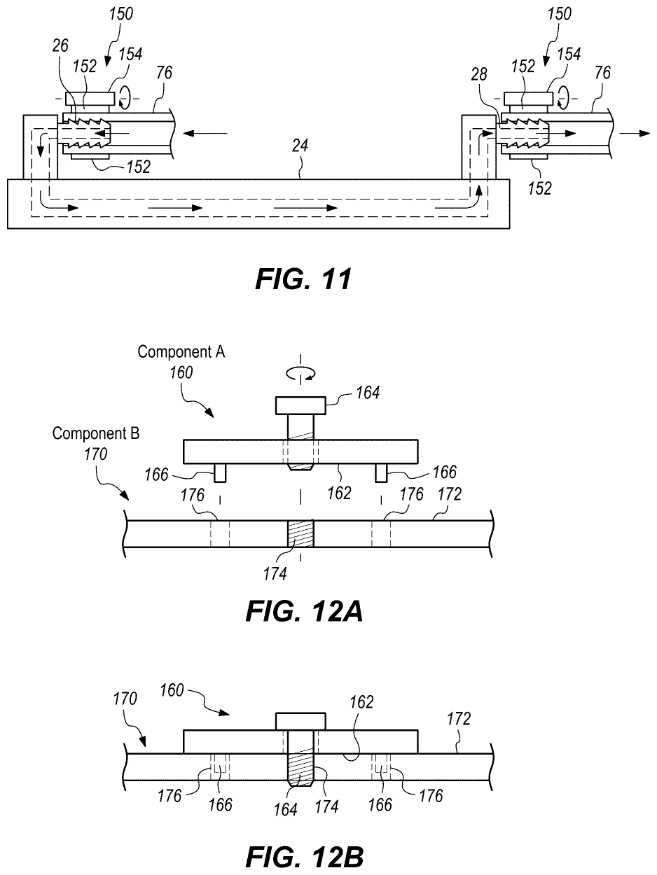

FIGS. 12A-B are schematic side views of a generic connection between two components that may be used to form connections according to various embodiments. The generic connection may be representative of the connection between (1) the handle bracket 111 and the first (shipping) adapter bracket 110, (2) the handle bracket 111 and the repositionable manifold assembly 70, (3) the first adapter bracket 110 and the top plate 100 of a cold plate 24, (4) the second adapter bracket 140 and the top plate 100 of a cold plate 24, (5) the second adapter bracket 140 and the stationary manifold assembly 60, and/or (6) the second adapter bracket 140 and the repositionable manifold assembly 70.

In reference to FIG. 12A, a first component (A) 160 includes a surface 162 having a cap screw 164 and a pair of guide pins 166 extending from the surface 162. A second component (B) 170 includes a surface 172 having a threaded hole 174 and a pair of guide holes 176. With the guide pins 166 aligned with the guide holes 176, the surface 162 of the first component (A) 160 may be moved toward the surface 172 of the second component (B) 170 such that the guide pins 166 extend into the guide holes 176 as shown in FIG. 12B. Once the two surfaces 162, 172 are in full contact, the cap screw 164 may be threaded into the threaded hole 174 to secure the two components (A), (B) 160, 170 together. However, if the guide pins 166 are not aligned with the guide holes 176, then the guide pins 166 will prevent the two surfaces 162, 172 from making full face-to-face contact and prevent the two components (A), (B) 160, 170 from being secured together. A successful connection is shown in FIG. 12B.

FIGS. 13A-D are schematic plan views of a cap screw 164 and two guide pins 166 as they may be arranged on a component 160 to form a connection. These various arrangements of the cap screw 164 and guide pins 166 may be used for connecting any two particular components of the apparatus. Unique arrangements of the cap screw 164 and guide pins 166 may be used for the connection of two particular components to prevent improper components from being connected and/or to prevent improper orientations of the components. It should be understood that a second component 170 must have matching arrangement of the threaded hole 174 and guide holes 176 in order to support a successful connection.

The terminology used herein is for the purpose of describing particular embodiments only and is not intended to limit the scope of the claims. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the embodiment.

The corresponding structures, materials, acts, and equivalents of all means or steps plus function elements in the claims below are intended to include any structure, material, or act for performing the function in combination with other claimed elements as specifically claimed. Embodiments have been presented for purposes of illustration and description, but it is not intended to be exhaustive or limited to the embodiments in the form disclosed. Many modifications and variations will be apparent to those of ordinary skill in the art after reading this disclosure. The disclosed embodiments were chosen and described as non-limiting examples to enable others of ordinary skill in the art to understand these embodiments and other embodiments involving modifications suited to a particular implementation.

What is claimed is:

1. An apparatus, comprising:
a server chassis containing a rear lateral row of processing unit assemblies secured to a system board, wherein each processing unit assembly includes a processing unit and a cold plate in thermal communication with the processing unit;
a repositionable manifold assembly positioned within the server chassis and including a first rigid manifold bracket, a first liquid supply manifold secured to the first rigid manifold bracket, and a first liquid return manifold secured to the first rigid manifold bracket;
a first plurality of flexible manifold hoses connected to the repositionable manifold assembly and extending rearward from the repositionable manifold assembly, wherein the first plurality of flexible manifold hoses include a first manifold liquid supply hose connected to an inlet to the first liquid supply manifold, a first manifold liquid return hose connected to an outlet from the first liquid return manifold and, for each cold plate in the rear lateral row, a cold plate liquid supply hose connected from an outlet of the first liquid supply manifold to an inlet to the cold plate and a cold plate liquid return hose connected from an outlet of the cold plate to an inlet of the first liquid return manifold; and
wherein the first repositionable manifold assembly is selectively securable in an operative position forward of the rear lateral row of processing unit assemblies and extends laterally over a plurality of components on the system board, and wherein the first repositionable manifold assembly is selectively securable in a service position rearward of the plurality of components to enable a service operation on any one or more of the plurality of components without disconnecting any of the first plurality of flexible manifold hoses.

2. The apparatus of claim 1, further comprising:
a first adapter bracket selectively securable to one or more of the cold plates in the rear lateral row of processing unit assemblies, wherein the repositionable manifold assembly is selectively securable in the service position by selectively securing the rigid manifold bracket of the repositionable manifold assembly to the first adapter bracket that has been secured to the one or more cold plates.

3. The apparatus of claim 2, wherein the first adapter bracket includes a first fastener part, the rigid manifold bracket includes a second fastener part, and the repositionable manifold assembly is selectively securable to the first adapter bracket by securing the first fastener part to the second fastener part.

4. The apparatus of claim 3, wherein the first fastener part is selected from a keyhole slot and a T-pin that is selectively securable to the keyhole slot by sliding a head of the T-pin into the keyhole slot, and wherein the second fastener part is the other of the keyhole slot or the T-pin.

5. The apparatus of claim 3, wherein the first adapter bracket includes two or more of the first fastener parts laterally spaced apart and the rigid manifold bracket includes two or more of the second fastener parts aligned with the two or more of the first fastener parts.

6. The apparatus of claim 2, wherein the first rigid manifold bracket includes a first lateral end and a second lateral end, wherein the repositionable manifold assembly is selectively securable in the operative position with the first lateral end of the first rigid manifold bracket connected to a first lateral side of the server chassis and the second lateral end of the first rigid manifold bracket connected to a second lateral side of the server chassis, and wherein the repositionable manifold assembly is selectively securable in the service position by coupling the first rigid manifold bracket to the first adapter bracket.

7. The apparatus of claim 6, wherein the repositionable manifold assembly is moveable between the operative position and the service position by rotating the repositionable manifold assembly about a lateral axis of the repositionable manifold assembly.

8. The apparatus of claim 3, wherein the first adapter bracket includes two or more face plates, each face plate having a pair of alignment pins and cap screw, wherein each cold plate includes a top plate having a pair of alignment holes and a threaded hole, and wherein the pair of alignment pins are insertable into the pair of alignment holes, thereby aligning the cap screw and the threaded hole so that the cap screw may be threaded into the threaded hole to secure one of the face plates to the top plate of one of the cold plates.

9. The apparatus of claim 8, wherein the first rigid manifold bracket spans between first and second lateral sides of the server chassis and includes a first lateral end selectively securable to the first lateral side of the server chassis and a second lateral end selectively securable to the second lateral side of the server chassis.

10. The apparatus of claim 1, wherein, for each cold plate in the rear lateral row, the cold plate includes a barbed liquid inlet coupling that is connected to one of the cold plate liquid supply hoses and a barbed liquid outlet coupling that is connected to one of the cold plate liquid return hoses.

11. The apparatus of claim 10, further comprising:
a plurality of hose clamps, wherein, for each cold plate liquid supply hose, one of the hose clamps secures an end of the cold plate liquid supply hose to one of the barbed liquid inlet couplings, and wherein, for each cold plate liquid return hose, one of the hose clamps secures an end of the cold plate liquid return hose to one of the barbed liquid outlet couplings.

12. The apparatus of claim 1, wherein each processing unit is a graphics processing unit.

13. The apparatus of claim 1, wherein the rear lateral row of processing unit assemblies includes four processing unit assemblies positioned side-by-side.

14. The apparatus of claim 1, wherein the plurality of components on the system board form a front row of processing unit assemblies forward of the rear row of processing unit assemblies, further comprising:
a stationary manifold assembly secured in the server chassis forward of the front row of processing unit assemblies; and
a second plurality of flexible manifold hoses connected to the stationary manifold assembly and extending rearward from the stationary manifold assembly, wherein the second plurality of flexible manifold hoses include a second manifold liquid supply hose connected to an inlet to the second liquid supply manifold, a second manifold liquid return hose connected to an outlet from the second liquid return manifold and, for each cold plate in the front row, a cold plate liquid supply hose connected from an outlet of the second liquid supply manifold to an inlet to the cold plate and a cold plate liquid return hose connected from an outlet of the cold plate to an inlet of the second liquid return manifold.

15. The apparatus of claim 14, wherein the first manifold liquid supply hose and the first liquid return hose extend rearward from the repositionable manifold assembly and out the rear of the server chassis, and wherein the second liquid supply hose and the second liquid return hose extend rearward from the stationary manifold assembly and out the rear of the server chassis.

16. The apparatus of claim 15, wherein the first manifold liquid supply hose is connected to a first lateral side of the rear liquid supply manifold and extends rearward along a first lateral side of the server chassis, the rear liquid return hose is connected to a second lateral side of the rear liquid return manifold and extends rearward along a second lateral side of the server chassis, the second manifold liquid supply hose is connected to a first lateral side of the second liquid supply manifold and extends rearward along the first lateral side of the server chassis, and the second manifold liquid return hose is connected to a second lateral side of the second liquid return manifold and extends rearward along the second lateral side of the server chassis.

17. The apparatus of claim 15, wherein, for each cold plate in the rear lateral row and each cold plate in the front lateral row, the cold plate liquid supply hose and the cold plate liquid return hose that are connected to the cold plate do not pass over any other cold plate in the same row as the cold plate.

18. The apparatus of claim 3, further comprising:
a handle bracket selectively securable between the first adapter bracket and the first rigid manifold bracket with the first adapter bracket secured to the one or more of the cold plates in the rear lateral row and with the repositionable manifold assembly placed in a shipping position.

19. A method of using the apparatus of claim 2, comprising:
connecting the first adapter bracket to one or more of the cold plates in a rear lateral row of processing unit assemblies;
disconnecting the repositionable manifold from the operative position;
moving the disconnected repositionable manifold rearward from the operative position to the service position to allow access to the plurality of components on the system board without disconnecting any of the first plurality of flexible manifold hoses;
temporarily fastening the repositionable manifold to the first adapter bracket with the repositionable manifold in the service position; and
performing the service operation on any one or more of the plurality of components on the system board while the repositionable manifold is temporarily fastened to the first adapter bracket.

20. The method of claim 19, wherein moving the disconnected repositionable manifold assembly rearward from the operative position to the service position includes rotating the repositionable manifold assembly around a lateral axis.
